(19) United States
(12) Patent Application Publication
(10) Pub. No.: US 2024/0234203 A1
(43) Pub. Date: Jul. 11, 2024

(54) SEMICONDUCTOR DEVICE HAVING LOW DIELECTRIC CAPACITANCE AND GOOD ELECTRICAL BREAKDOWN PERFORMANCE, AND METHOD FOR MANUFACTURING THE SAME

(71) Applicant: TAIWAN SEMICONDUCTOR MANUFACTURING COMPANY, LTD., Hsinchu (TW)

(72) Inventors: Ting-Ya LO, Hsinchu (TW); Shao-Kuan LEE, Hsinchu (TW); GARY LIU, Hsinchu (TW); Zi-Yi YANG, Hsinchu (TW); Kuang-Wei YANG, Hsinchu (TW); Jing-Ting SU, Hsinchu (TW); Chi-Lin TENG, Hsinchu (TW); Hsin-Yen HUANG, Hsinchu (TW); Hsiao-Kang CHANG, Hsinchu (TW); Shau-Lin SHUE, Hsinchu (TW)

(73) Assignee: TAIWAN SEMICONDUCTOR MANUFACTURING COMPANY, LTD., Hsinchu (TW)

(21) Appl. No.: 18/150,617

(22) Filed: Jan. 5, 2023

(51) Int. Cl. H01L 21/768; H01L 23/522

(52) U.S. Cl. CPC H01L 21/76831; H01L 21/76847; H01L 21/76877; H01L 23/5226

(57) ABSTRACT

A method for manufacturing a semiconductor device includes: preparing a conductive structure that includes a plurality of conductive features, adjacent two of which are spaced apart from each other by a corresponding one of a plurality of recesses;

conformally forming a dielectric capping layer on the conductive structure; forming a dielectric cover layer on the dielectric capping layer to fill the recesses; and removing a portion of the dielectric cover layer and a portion of the dielectric capping layer to expose the conductive features, so as to form a plurality of spacer features respectively filled in the recesses; wherein each of the dielectric capping layer and the dielectric cover layer is made of a dielectric material doped with metal oxide.

### BACKGROUND

The integration density of various electronic components, such as transistors, diodes, resistors, capacitors, etc., is being improved continuously in the semiconductor industry by continual reduction in minimum feature sizes. As the feature sizes are decreased, making a semiconductor device with both low dielectric capacitance and good electrical breakdown performance becomes particularly challenging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method for manufacturing a semiconductor device in accordance with some embodiments.

FIGS. 2 to 9 are schematic sectional views illustrating intermediate stages of the method for manufacturing a semiconductor device in accordance with some embodiments.

FIG. 10 is a flow chart illustrating a method for manufacturing a semiconductor device in accordance with some embodiments.

FIGS. 11 to 18 are schematic sectional views illustrating intermediate stages of the method for manufacturing a semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

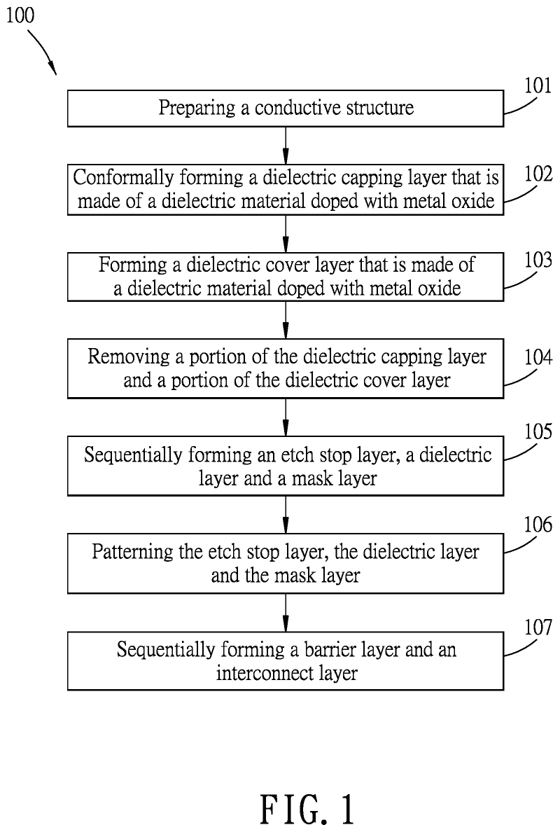

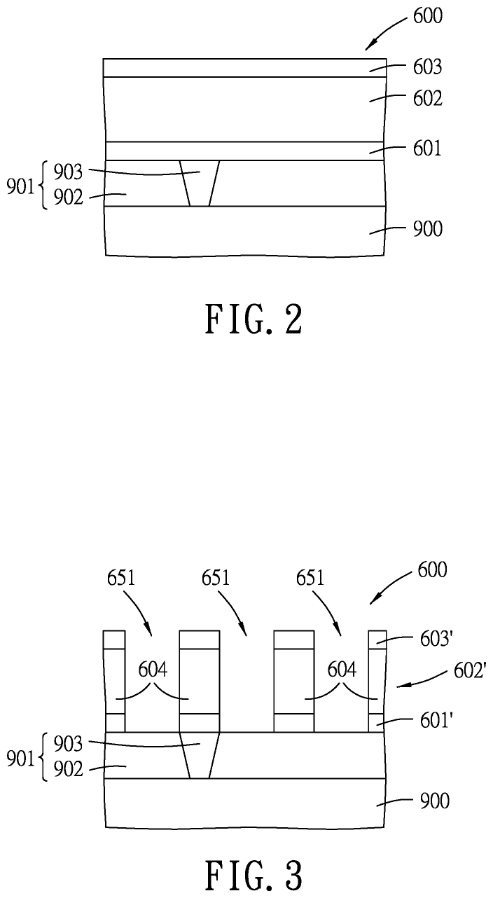

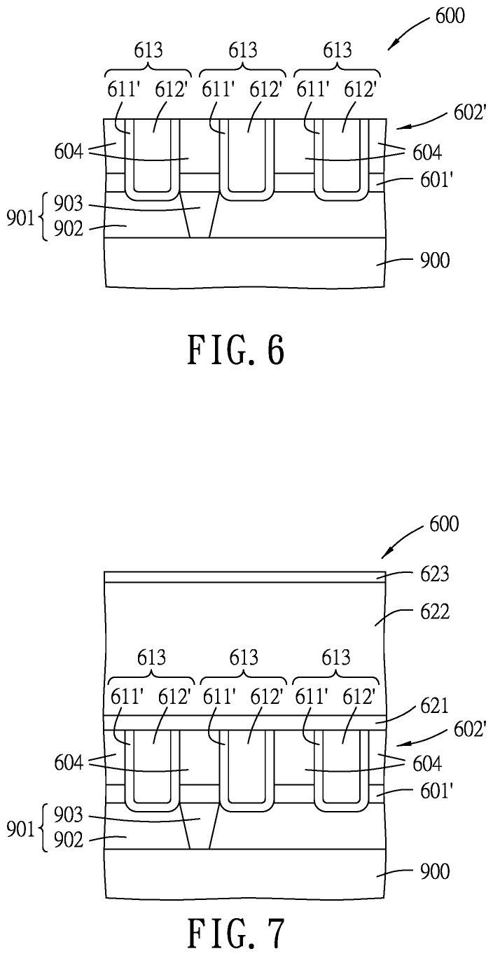

FIG. 1 is a flow chart illustrating a method 100 for manufacturing a semiconductor device in accordance with some embodiments. FIGS. 2 to 9 are schematic sectional views of semiconductor structures 600 during various stages of the method 100. The method 100 and the semiconductor structures 600 are collectively described below. However, additional steps can be provided before, after or during the method 100, and some of the steps described herein may be replaced by other steps or be eliminated. Similarly, further additional features may be present in the semiconductor structures 600, and/or features present may be replaced or eliminated in additional embodiments.

Referring to FIGS. 1, 2 and 3, the method 100 begins at step 101, where a conductive structure 602′ is prepared on a first interconnect layer 901 disposed over a substrate 900. The conductive structure 602′ includes a plurality of conductive features 604 (e.g., conductive metal lines), adjacent two of which are spaced apart from each other by a corresponding one of a plurality of recesses 651. One of the conductive features 604 is electrically connected to a conductive interconnect 903.

The first interconnect layer 901 includes a dielectric layer 902 provided with at least one opening, and at least one conductive interconnect 903 (e.g., a conductive via contact) filled in the opening. In some embodiments, the dielectric layer 902 may be formed on the substrate 900 by a suitable deposition process known to those skilled in the art of semiconductor fabrication, such as atomic layer deposition (ALD), chemical vapor deposition (CVD), physical vapor deposition (PVD), other suitable techniques, or combinations thereof; and a conductive material may be filled into the opening and then subjected to a planarization treatment (e.g., chemical mechanical planarization (CMP)) to form the conductive interconnect 903 in the opening. In some embodiments, the conductive material for forming the conductive interconnect 903 may be provided as multiple layers having varying composition, and may be filled into the opening by a suitable deposition process known in the art of semiconductor fabrication, such as electroless plating, electroplating, sputter deposition, PVD, CVD, ALD, other suitable techniques, or combinations thereof. In some embodiments, the dielectric layer 902 may be made of a dielectric material, such as silicon oxide, SiOC-based materials (e.g., SiOCH), borophosphosilicate glass (BPSG), undoped silicate glass (USG), fluorinated silicate glass (FSG), high-density plasma (HDP) oxide, plasma-enhanced TEOS (PETEOS), fluorine-doped silicon oxide, carbon-doped silicon oxide, porous silicon oxide, porous carbon-doped silicon oxide, organic polymers, or silicone based polymers. In some embodiments, silicon oxide may be formed from tetraethyl orthosilicate (TEOS). In some embodiments, the conductive material for forming the conductive interconnect 903 may be, for example, copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), gold (Au), aluminum (Al), or alloys thereof. In some embodiments, the conductive interconnect 903 may have a thickness that falls within a range of from about 50 Å to about 500 Å.

In some embodiments, the substrate 900 may be a semiconductor substrate, e.g., an elemental semiconductor or a compound semiconductor. An elemental semiconductor is composed of a single species of atoms, such as silicon (Si) or germanium (Ge) in column IV of the periodic table. A compound semiconductor is composed of two or more elements, such as silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or the like. The compound semiconductor may have a gradient feature in which the composition thereof changes from one ratio at one location to another ratio at another location in the compound semiconductor. The compound semiconductor may be formed over a silicon substrate, and the compound semiconductor may be strained. In some embodiments, the substrate 900 may include a multilayer compound semiconductor device. Alternatively, the substrate 900 may include a non-semiconductor material, such as glass, fused quartz, or calcium fluoride. Furthermore, in some embodiments, the substrate 900 may be a silicon on insulator (SOI) substrate (e.g., silicon germanium on insulator (SGOI)). Generally, an SOI substrate includes a layer of a semiconductor material such as epitaxial silicon, germanium, silicon germanium, or combinations thereof. The substrate may be doped with a p-type dopant, such as boron (Br), aluminum, gallium (Ga), or the like, or may alternatively be doped with an n-type dopant, as is known in the art. In some embodiments, the substrate 900 may include a doped epitaxial layer. Shallow trench isolation (STI) regions (not shown) may be formed in the substrate 900 to isolate active regions (not shown), such as source or drain regions of an integrated circuit device (not shown) in the substrate 900. In some embodiments, the integrated circuit device may include complementary metal-oxide semiconductor (CMOS) transistors, planar or vertical multi-gate transistors (e.g., FinFET devices), gate-all-around (GAA) devices, resistors, capacitors, diodes, transistors (e.g., field-effect transistors (FETs)), interconnects, or the like, based on practical applications. In addition, through-vias (not shown) may be formed to extend into the substrate 900 for electrically connecting features on opposite sides of the substrate 900.

As shown in FIG. 2, a glue layer 601, a conductive layer 602 and a mask layer 603 (e.g., a hard mask layer) are sequentially formed on the first interconnect layer 901.

The glue layer 601 can provide good adhesion to the conductive interconnect 903 and the conductive layer 602. In some embodiments, the glue layer 601 may be formed on the first interconnect layer 901 by a suitable deposition process known in the art of semiconductor fabrication, such as PVD, CVD, ALD, other suitable techniques, or combinations thereof. In some embodiments, the glue layer 601 may be made of a nitride of tantalum (Ta), titanium (Ti), or other suitable metals. In some embodiments, the glue layer 601 may have a thickness that falls within a range of from about 2 Å to about 100 Å. In some embodiments, the conductive layer 602 may be formed on the glue layer 601 by a suitable deposition process known in the art of semiconductor fabrication, such as

PVD, CVD, ALD, other suitable techniques, or combinations thereof. In some embodiments, the conductive layer 602 may be made of a conductive material, such as

Cu, Co, Ru, Mo, Cr, W, Mn, Rh, Ir, Ni, Pd, Pt, Ag, Au, Al, or alloys thereof. In some embodiments, the conductive layer 602 may have a thickness that falls within a range of from about 50 Å to about 500 Å. In some embodiments, the mask layer 603 may be formed on the conductive layer 602 by a suitable deposition process known in the art of semiconductor fabrication, such as PVD, CVD, ALD, other suitable techniques, or combinations thereof. In some embodiments, the mask layer 603 may be made of, for example, silicon oxide, silicon nitride, silicon carbide, silicon oxycarbide, silicon oxynitride, silicon carbonitride, silicon oxycarbonitride, cobalt, ruthenium, tungsten, titanium nitride, zirconium oxide, aluminum oxide, yttrium oxide, aluminum oxynitride, hafnium oxide, hafnium zirconium oxide, hafnium silicon oxide, hafnium silicon oxynitride, zirconium silicon oxide, hafnium zirconium silicon oxide, hafnium aluminum oxide, hafnium aluminum nitride, zirconium aluminum oxide, ytterbium oxide, other suitable materials, or combinations thereof.

As shown in FIG. 3, the mask layer 603 is patterned using photolithography and photoresist developing technology as is known to those skilled in the art of semiconductor fabrication. For example, the mask layer 603 may be patterned by 193 nm immersion lithography or extreme ultraviolet (EUV) lithography. A pattern formed in the patterned mask layer 603′ is then transferred to the conductive layer 602 and the glue layer 601 by one or more etching processes to form the conductive structure 602′ and the patterned glue layer 601′. The etching process for forming the conductive structure 602′ maybe implemented by, for example, reactive ion etching (RIE), plasma etching, deep RIE, atomic layer etching, etc., using an etching gas, such as CHF₃, CH₂F₂, CF₄, C₄F₈, C₄F₆, N₂, Ar, O₂, NF₃, CO₂, H₂, etc.

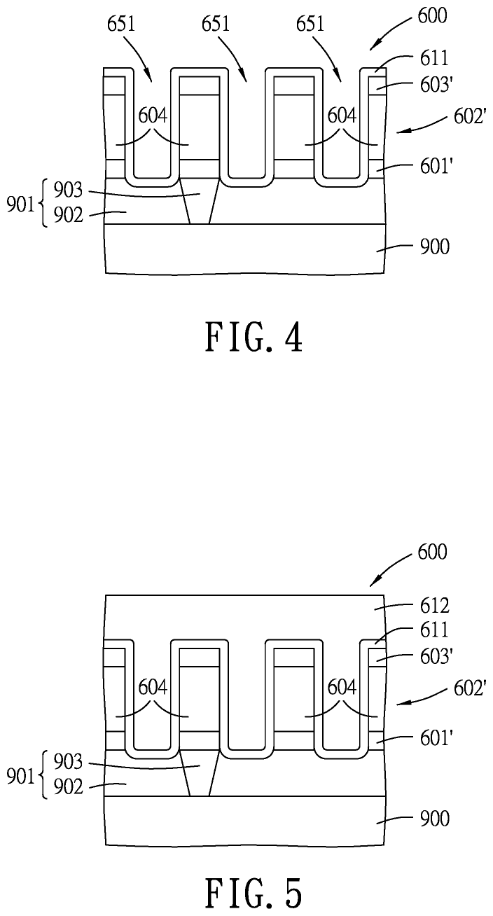

Referring to FIGS. 1 and 4, the method 100 then proceeds to step 102, where a dielectric capping layer 611 is conformally formed on the patterned mask layer 603′ and in the recesses 651. The dielectric capping layer 611 can provide good adhesion to the patterned glue layer 601′. In some embodiments, the dielectric capping layer 611 may be formed by a suitable deposition process known to those skilled in the art of semiconductor fabrication, such as PVD, CVD, plasma-enhanced chemical vapor deposition (PECVD), ALD, plasma-enhanced atomic layer deposition (PEALD), other suitable techniques, or combinations thereof. In some embodiments, the dielectric capping layer 611 may be made of a dielectric material doped with metal oxide. The dielectric material for forming the dielectric capping layer 611 may be, for example, silicon oxide (SiO), silicon oxycarbide (SiCO), silicon oxynitride (SiNO), silicon carbonitride (SiCN), silicon oxycarbonitride (SiCON), other suitable materials, or combinations thereof. The metal oxide doped in the dielectric material for forming the dielectric capping layer 611 may be, for example, aluminum oxide (AlOₓ), zirconium oxide (ZrOₓ), tin oxide (SnOₓ), lead oxide (PbOₓ), titanium oxide (TiOₓ), tungsten oxide (WOₓ), chromium oxide (CrOₓ), arsenic oxide (AsOₓ), other suitable materials, or combinations thereof. In some embodiments, a doping concentration of the metal oxide in the dielectric material for forming the dielectric capping layer 611 may fall within a range of from about 0.5% to about 10%. When the doping concentration falls outside of the range, the dielectric capping layer 611 may have a dielectric constant higher than what would be expected. In some embodiments, the dielectric capping layer 611 may have a thickness that falls within a range of from about 2 Å to about 50 Å.

Referring to FIGS. 1, 4 and 5, the method 100 then proceeds to step 103, where a dielectric cover layer 612 is formed on the dielectric capping layer 611 to fill the recesses 651. The dielectric cover layer 90 can provide good adhesion to the dielectric capping layer 611. In some embodiments, the dielectric cover layer 612 may be formed on the dielectric capping layer 611 by a suitable deposition process known to those skilled in the art of semiconductor fabrication, such as CVD, ALD, PECVD, PEALD, spin-on deposition, other suitable techniques, or combinations thereof. In some embodiments, the dielectric cover layer 612 may be made of a dielectric material doped with metal oxide. The dielectric material for forming the dielectric cover layer 612 may be, for example, a low-k dielectric material, such as SiCOH, which is a dielectric material containing silicon (Si), carbon (C), oxygen (O) and hydrogen (H) atoms. The metal oxide doped in the dielectric material for forming the dielectric cover layer 612 may be, for example, AlOₓ, ZrOₓ, SnOₓ, PbOₓ, TiOₓ, WOₓ, CrOₓ, AsOₓ, other suitable materials, or combinations thereof. In some embodiments, a doping concentration of the metal oxide in the dielectric material for forming the dielectric cover layer 612 may fall within a range of from about 0.5% to about 10%. When the doping concentration falls outside of the range, the dielectric cover layer 612 may have a dielectric constant higher than what would be expected.

Referring to FIGS. 1, 5 and 6, the method 100 then proceeds to step 104, where a portion of the dielectric cover layer 612, a portion of the dielectric capping layer 611 and the patterned mask layer 603′ are removed to expose top surfaces of the conductive features 604, so as to form a plurality of spacer features 613 respectively filled in the recesses 651 (see FIG. 3). Each of the spacer features 613 includes a spacer element 612′ that is originated from the dielectric cover layer 612, and a spacer film 611′ that is originated from the dielectric capping layer 611 and that covers side and bottom surfaces of the spacer element 612′. In some embodiments, the dielectric cover layer 612 and the dielectric capping layer 611 may be subjected to a suitable planarization process known to those skilled in the art of semiconductor fabrication, such as CMP, to remove the portion of the dielectric cover layer 612, the portion of the dielectric capping layer 611 and the patterned mask layer 603′, so as to form the spacer features 613 that has top surfaces horizontally flush with those of the conductive features 604.

Referring to FIGS. 1 and 7, the method 100 then proceeds to step 105, where an etch stop layer 621, a dielectric layer 622 and a mask layer 623 (e.g., a hard mask layer) are sequentially formed on the conductive features 604 and the spacer features 613. In some embodiments, the etch stop layer 621 may be formed on the conductive features 604 and the spacer features 613 by a suitable deposition process known to those skilled in the art of semiconductor fabrication, such as PVD, CVD, ALD, PECVD, PEALD, other suitable techniques, or combinations thereof. In some embodiments, the etch stop layer 621 may be made of aluminum compounds (e.g., aluminum nitride (AlNₓ), aluminum oxynitride (AlON), aluminum oxide, etc.), silicon compounds (e.g., SiO, SiCO, SiCN, silicon nitride (SiN), SiCON, etc.), other suitable materials, or combinations thereof. In some embodiments, the etch stop layer 621 may have a thickness that falls within a range of from about 2 Å to about 200 Å. In some embodiments, the dielectric layer 622 may be formed on the etch stop layer 621 by a suitable deposition process known to those skilled in the art of semiconductor fabrication, such as PVD, CVD, ALD, PECVD, PEALD, other suitable techniques, or combinations thereof. In some embodiments, the dielectric layer 622 may be made of a low-k dielectric material, such as silicon oxide, silicon nitride, silicon carbide, silicon oxycarbide, silicon oxynitride, silicon carbonitride, silicon oxycarbonitride, other suitable materials, or combinations thereof. In some embodiments, the mask layer 623 may be formed on the dielectric layer 622 by a suitable deposition process known to those skilled in the art of semiconductor fabrication, such as PVD, CVD, ALD, other suitable techniques, or combinations thereof. In some embodiments, the mask layer 623 may be made of, for example, silicon oxide, silicon nitride, silicon carbide, silicon oxycarbide, silicon oxynitride, silicon carbonitride, silicon oxycarbonitride, cobalt, ruthenium, tungsten, titanium nitride, zirconium oxide, aluminum oxide, yttrium oxide, aluminum oxynitride, hafnium oxide, hafnium zirconium oxide, hafnium silicon oxide, hafnium silicon oxynitride, zirconium silicon oxide, hafnium zirconium silicon oxide, hafnium aluminum oxide, hafnium aluminum nitride, zirconium aluminum oxide, ytterbium oxide, other suitable materials, or combinations thereof.

Referring to FIGS. 1, 7 and 8, the method 100 then proceeds to step 106, where the mask layer 623, the dielectric layer 622 and the etch stop layer 621 are patterned to form a patterned mask layer 623′, a patterned dielectric layer 622′ and a patterned etch stop layer 621′. The patterned dielectric layer 622′ and the patterned etch stop layer 621′ cooperatively define a through hole 652 that exposes a predetermined one of the conductive features 604. In some embodiments, the mask layer 623 is patterned using photolithography and photoresist developing technology as is known to those skilled in the art of semiconductor fabrication. For example, the mask layer 623 may be patterned by 193 nm immersion lithography or EUV lithography. A pattern formed in the patterned mask layer 623′ is then transferred to the dielectric layer 622 and the etch stop layer 621 by one or more etching processes to form the patterned dielectric layer 622′ and the patterned etch stop layer 621′.

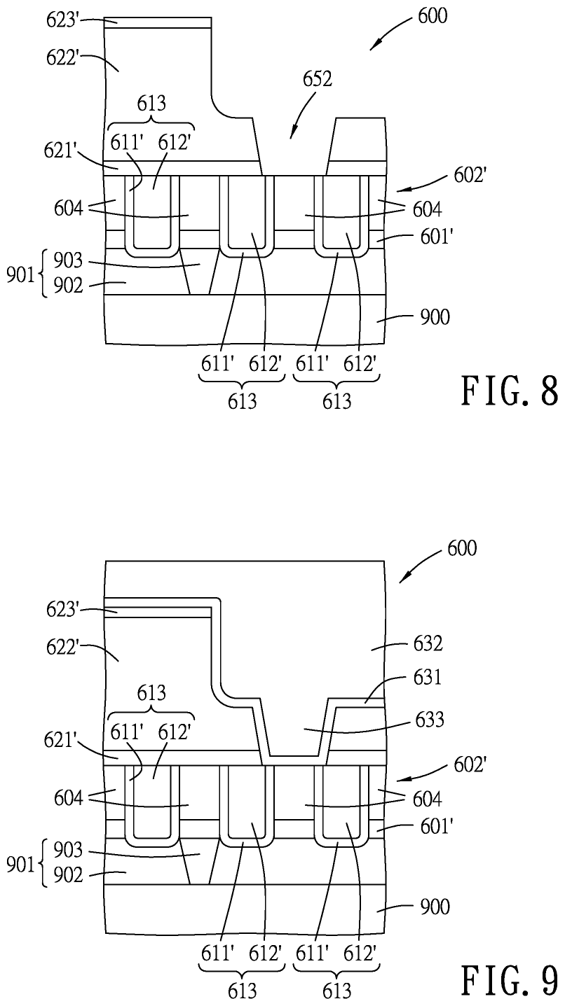

Referring to FIGS. 1, 8 and 9, the method 100 then proceeds to step 107, where a barrier layer 631 is conformally formed on the semiconductor structure 600 as shown in FIG. 8, and then a second interconnect layer 632 is formed on the barrier layer 631. The second interconnect layer 632 includes a conductive interconnect 633 that is filled in the through hole 652, and that is electrically connected to the predetermined one of the conductive features 604 through the barrier layer 631. The barrier layer 631 can prevent electromigration. In some embodiments, the barrier layer 631 may be formed on the semiconductor structure 600 as shown in FIG. 8 by a suitable deposition process known to those skilled in the art of semiconductor fabrication, such as CVD. In some embodiments, the barrier layer 631 may be made of, for example, Ru, Mn, Co, Cr, titanium nitride (TiN), titanium tungsten (TiW), Ta, tantalum nitride (TaN), tungsten nitride (WN), other suitable materials, or combinations thereof. In some embodiments, the second interconnect layer 632 may be formed on the barrier 631 by a suitable deposition process known in the art of semiconductor fabrication, such as electroless plating, electroplating, sputter deposition, PVD, CVD, ALD, other suitable techniques, or combinations thereof. In some embodiments, the second interconnect layer 632 may be made of a conductive material, such as Cu, Co, Ru, Mo, Cr, W, Mn, Rh, Ir, Ni, Pd, Pt, Ag, Au, Al, or alloys thereof.

In some embodiments, by virtue of each of the dielectric capping layer 611 and the dielectric cover layer 612 being made of a dielectric material doped with metal oxide, the semiconductor structure 600 can have both low dielectric capacitance and good electrical breakdown performance.

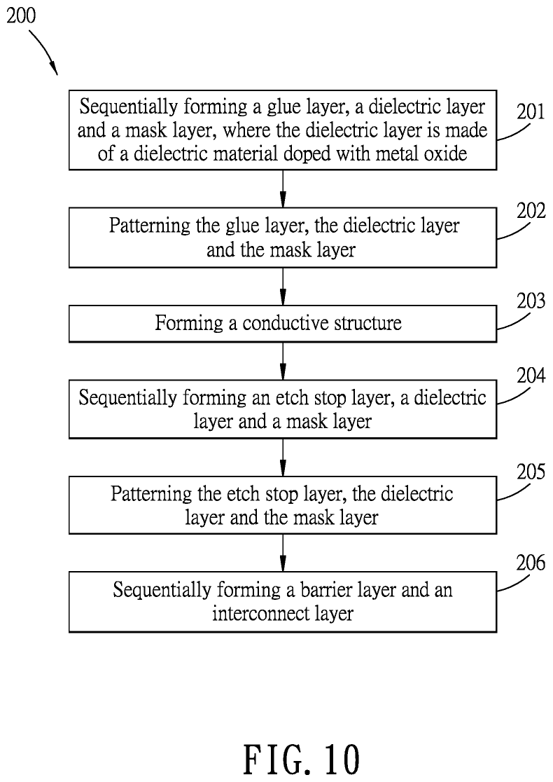

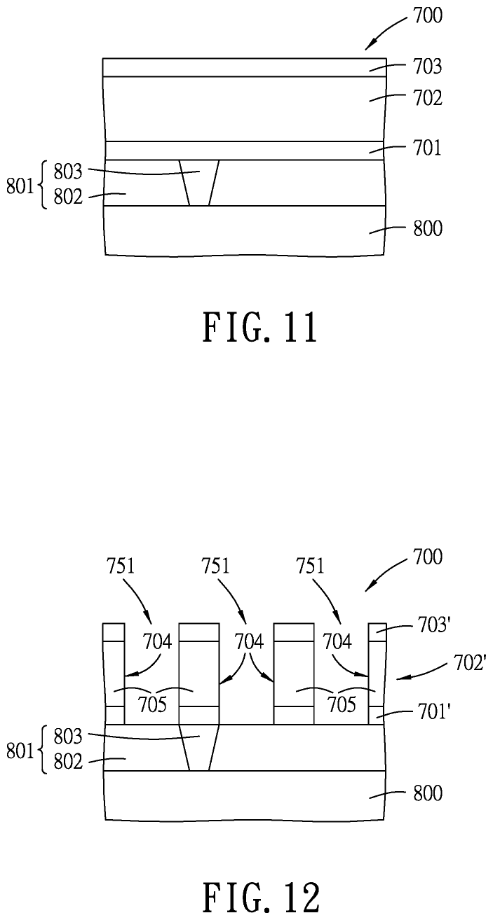

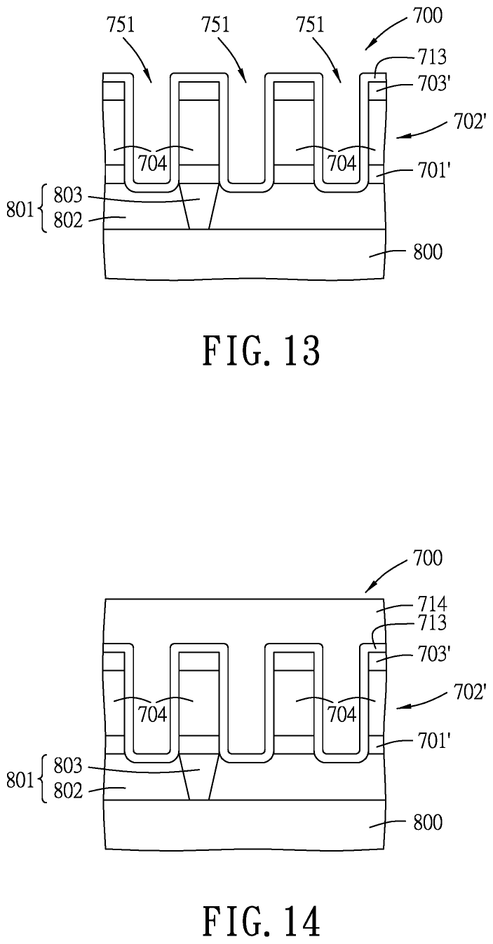

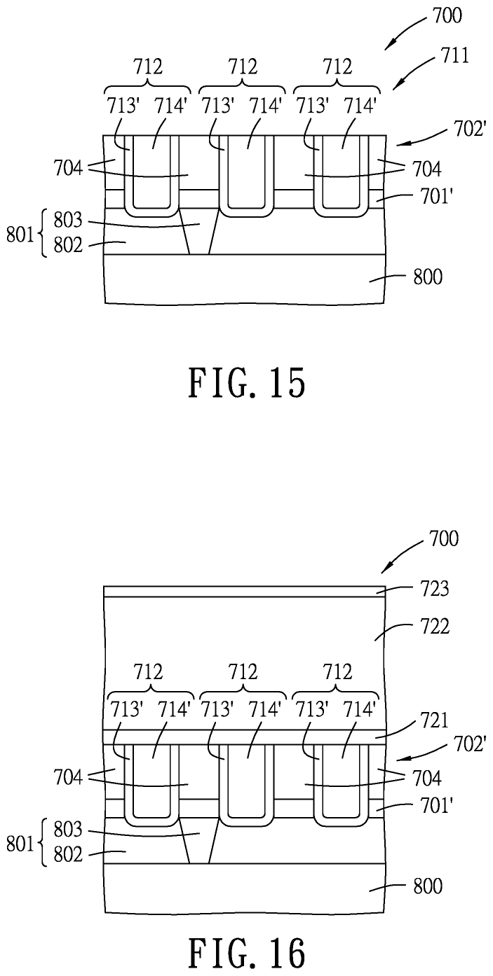

FIG. 10 is a flow chart illustrating a method 200 for manufacturing a semiconductor device in accordance with some embodiments. FIGS. 11 to 18 are schematic sectional views of semiconductor structures 700 during various stages of the method 200. The method 200 and the semiconductor structures 700 are collectively described below. However, additional steps can be provided before, after or during the method 200, and some of the steps described herein may be replaced by other steps or be eliminated. Similarly, further additional features may be present in the semiconductor structures 700, and/or features present may be replaced or eliminated in additional embodiments.

Referring to FIGS. 10 and 11, the method 200 begins at step 201, where a glue layer 701, a dielectric layer 702 and a mask layer 703 (e.g., a hard mask layer) are sequentially formed on a first interconnect layer 801 disposed over a substrate 800.

The first interconnect layer 801 includes a dielectric layer 802 provided with at least one opening, and at least one conductive interconnect 803 (e.g., a conductive via contact) filled in the opening. Other details regarding the first interconnect layer 801 are the same as or similar to those of the first interconnect layer 901 described above with reference to FIGS. 2 and 3. In addition, details regarding the substrate 800 are the same as or similar to those of the substrate 900 described above with reference to FIGS. 2 and 3.

The glue layer 701 can provide good adhesion to the conductive interconnect 803. In some embodiments, the glue layer 701 may be formed on the first interconnect layer 801 by a suitable deposition process known in the art of semiconductor fabrication, such as PVD, CVD, ALD, other suitable techniques, or combinations thereof. In some embodiments, the glue layer 701 may be made of a nitride of Ta, Ti, or other suitable metals. In some embodiments, the glue layer 701 may have a thickness that falls within a range of from about 2 Å to about 100 Å. In some embodiments, the dielectric layer 702 may be formed on the glue layer 701 by a suitable deposition process known to those skilled in the art of semiconductor fabrication, such as CVD, ALD, PECVD, PEALD, spin-on deposition, other suitable techniques, or combinations thereof. In some embodiments, the dielectric layer 702 may be made of a dielectric material doped with metal oxide. The dielectric material for forming the dielectric layer 702 may be, for example, a low-k dielectric material, such as SiCOH. The metal oxide doped in the dielectric layer for forming the dielectric layer 702 may be, for example, AlOₓ, ZrOₓ, SnOₓ, PbOₓ, TiOₓ, WOₓ, CrOₓ, AsOₓ, other suitable materials, or combinations thereof. In some embodiments, a doping concentration of the metal oxide in the dielectric material for forming the dielectric layer 702 may fall within a range of from about 0.5% to about 10%. When the doping concentration falls outside of the range, the dielectric layer 702 may have a dielectric constant higher than what would be expected. In some embodiments, the dielectric layer 702 may have a thickness that falls within a range of from about 50 Å to about 500 Å. In some embodiments, the mask layer 703 may be formed on the dielectric layer 702 by a suitable deposition process known in the art of semiconductor fabrication, such as PVD, CVD, ALD, other suitable techniques, or combinations thereof. In some embodiments, the mask layer 703 may be made of, for example, silicon oxide, silicon nitride, silicon carbide, silicon oxycarbide, silicon oxynitride, silicon carbonitride, silicon oxycarbonitride, cobalt, ruthenium, tungsten, titanium nitride, zirconium oxide, aluminum oxide, yttrium oxide, aluminum oxynitride, hafnium oxide, hafnium zirconium oxide, hafnium silicon oxide, hafnium silicon oxynitride, zirconium silicon oxide, hafnium zirconium silicon oxide, hafnium aluminum oxide, hafnium aluminum nitride, zirconium aluminum oxide, ytterbium oxide, other suitable materials, or combinations thereof.

Referring to FIGS. 10, 11 and 12, the method 200 then proceeds to step 202, where the glue layer 701, the dielectric layer 702 and the mask layer 703 are patterned to form a patterned glue layer 701′, a spacer structure 702′ and a patterned mask layer 703′. The spacer structure 702′ includes a plurality of spacer features 704, adjacent two of which are spaced apart from each other by a corresponding one of a plurality of recesses 751, and each of which includes a spacer element 705. One of the spacer features 704 is aligned with the conductive interconnect 803. In some embodiments, the mask layer 703 may be patterned using photolithography and photoresist developing technology as is known to those skilled in the art of semiconductor fabrication. For example, the mask layer 703 may be patterned by 193 nm immersion lithography or EUV lithography. A pattern formed in the patterned mask layer 703′ is then transferred to the dielectric layer 702 and the glue layer 701 by one or more etching processes to form the spacer structure 702′ and the patterned glue layer 701′.

Referring to FIGS. 10, 13, 14 and 15, the method 200 then proceeds to step 203, where a conductive structure 711 is formed. The conductive structure 711 includes a plurality of conductive features 712 that are respectively filled in the recesses 751. Each of the conductive features 712 includes a conductive element 714′ (e.g., a conductive metal line), and a barrier film 713′ that covers side and bottom surfaces of the conductive element 714′. In some embodiments, the conductive structure 711 may be formed by: (a) conformally forming a barrier layer 713, which is for forming the barrier films 713′ of the conductive features 712, on the patterned mask layer 703′ and in the recesses 751; (b) forming a conductive layer 714, which is for forming the conductive elements 714′ of the conductive features 712, on the barrier layer 713 to fill the recesses 751; and (c) removing a portion of the conductive layer 714, a portion of the barrier layer 713 and the patterned mask layer 703′ to expose top surfaces of the spacer features 704, so as to form the conductive features 712 respectively filled in the recesses 751. The barrier layer 713 can prevent electromigration. In some embodiments, the barrier layer 713 may be formed on the patterned mask layer 703′ and in the recesses 751 by a suitable deposition process known to those skilled in the art of semiconductor fabrication, such as CVD. In some embodiments, the barrier layer 713 may be made of, for example, Ru, Mn, Co, Cr, TiN, TiW, Ta, TaN, WN, other suitable materials, or combinations thereof. In some embodiments, the conductive layer 714 may be formed on the barrier layer 713 by a suitable deposition process known in the art of semiconductor fabrication, such as electroless plating, electroplating, sputter deposition, PVD, CVD, ALD, other suitable techniques, or combinations thereof. In some embodiments, the conductive layer 714 may be made of a conductive material, such as Cu, Co, Ru, Mo, Cr, W, Mn, Rh, Ir, Ni, Pd, Pt, Ag, Au, Al, or alloys thereof. In some embodiments, the conductive layer 714 and the barrier layer 713 may be subjected to a suitable planarization process known to those skilled in the art of semiconductor fabrication, such as CMP, to remove the portion of the conductive layer 714, the portion of the barrier layer 713 and the patterned mask layer 703′, so as to form the conductive features 712 that has top surfaces horizontally flush with those of the spacer features 704.

Referring to FIGS. 10 and 16, the method 200 then proceeds to step 204, where an etch stop layer 721, a dielectric layer 722 and a mask layer 723 (e.g., a hard mask layer) are sequentially formed on the spacer features 704 and the conductive features 712. In some embodiments, the etch stop layer 721 may be formed on the spacer features 704 and the conductive features 712 by a suitable deposition process known to those skilled in the art of semiconductor fabrication, such as PVD, CVD, ALD, PECVD, PEALD, other suitable techniques, or combinations thereof. In some embodiments, the etch stop layer 721 may be made of aluminum compounds (e.g., AlNx, AlON, AlOx, etc.), silicon compounds (e.g., SiO, SiCO, SiCN, SiN, SiCON, etc.), other suitable materials, or combinations thereof. In some embodiments, the etch stop layer 721 may have a thickness that falls within a range of from about 2 Å to about 200 Å. In some embodiments, the dielectric layer 722 may be formed on the etch stop layer 721 by a suitable deposition process known to those skilled in the art of semiconductor fabrication, such as PVD, CVD, ALD, PECVD, PEALD, other suitable techniques, or combinations thereof. In some embodiments, the dielectric layer 722 may be made of a low-k dielectric material, such as silicon oxide, silicon nitride, silicon carbide, silicon oxycarbide, silicon oxynitride, silicon carbonitride, silicon oxycarbonitride, other suitable materials, or combinations thereof. In some embodiments, the mask layer 723 may be formed on the dielectric layer 722 by a suitable deposition process known to those skilled in the art of semiconductor fabrication, such as PVD, CVD, ALD, other suitable techniques, or combinations thereof. In some embodiments, the mask layer 723 may be made of, for example, silicon oxide, silicon nitride, silicon carbide, silicon oxycarbide, silicon oxynitride, silicon carbonitride, silicon oxycarbonitride, cobalt, ruthenium, tungsten, titanium nitride, zirconium oxide, aluminum oxide, yttrium oxide, aluminum oxynitride, hafnium oxide, hafnium zirconium oxide, hafnium silicon oxide, hafnium silicon oxynitride, zirconium silicon oxide, hafnium zirconium silicon oxide, hafnium aluminum oxide, hafnium aluminum nitride, zirconium aluminum oxide, ytterbium oxide, other suitable materials, or combinations thereof.

Referring to FIGS. 10, 16 and 17, the method 200 then proceeds to step 205, where the mask layer 723, the dielectric layer 722 and the etch stop layer 721 are patterned to form a patterned mask layer 723′, a patterned dielectric layer 722′ and a patterned etch stop layer 721′. The patterned dielectric layer 722′ and the patterned etch stop layer 721′ cooperatively define a through hole 752 that exposes a predetermined one of the conductive features 712. In some embodiments, the mask layer 723 may be patterned using photolithography and photoresist developing technology as is known to those skilled in the art of semiconductor fabrication. For example, the mask layer 723 may be patterned by 193 nm immersion lithography or EUV lithography. A pattern formed in the patterned mask layer 723′ is then transferred to the dielectric layer 722 and the etch stop layer 721 by one or more etching processes to form the patterned dielectric layer 722′ and the patterned etch stop layer 721′.

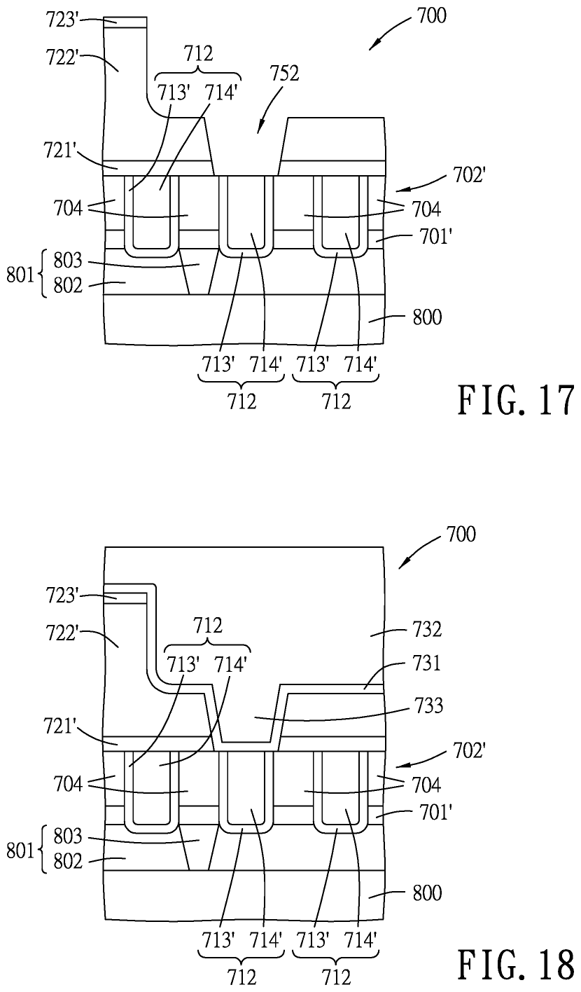

Referring to FIGS. 10, 17 and 18, the method 200 then proceeds to step 206, where a barrier layer 731 is conformally formed on the semiconductor structure 700 as shown in FIG. 17, and then a second interconnect layer 732 is formed on the barrier layer 731. The second interconnect layer 732 includes a conductive interconnect 733 that is filled in the through hole 752, and that is electrically connected to the predetermined one of the conductive features 712 through the barrier layer 731. The barrier layer 731 can prevent electromigration. In some embodiments, the barrier layer 731 may be formed on the semiconductor structure 700 as shown in FIG. 17 by a suitable deposition process known to those skilled in the art of semiconductor fabrication, such as CVD. In some embodiments, the barrier layer 631 may be made of, for example, Ru, Mn, Co, Cr, TiN, TiW, Ta, TaN, WN, other suitable materials, or combinations thereof. In some embodiments, the second interconnect layer 732 may be formed on the barrier layer 731 by a suitable deposition process known to those skilled in the art of semiconductor fabrication, such as electroless plating, electroplating, sputter deposition, PVD, CVD, ALD, other suitable techniques, or combinations thereof. In some embodiments, the second interconnect layer 732 may be made of a conductive material, such as Cu, Co, Ru, Mo, Cr, W, Mn, Rh, Ir, Ni, Pd, Pt, Ag, Au, Al, or alloys thereof.

In some embodiments, by virtue of the dielectric layer 702 being made of a dielectric material doped with metal oxide, the semiconductor structure 700 can have both low dielectric capacitance and good electrical breakdown performance.

In accordance with some embodiments of the present disclosure, a method for manufacturing a semiconductor device includes: preparing a conductive structure that includes a plurality of conductive features, adjacent two of which are spaced apart from each other by a corresponding one of a plurality of recesses; conformally forming a dielectric capping layer on the conductive structure; forming a dielectric cover layer on the dielectric capping layer to fill the recesses; and removing a portion of the dielectric cover layer and a portion of the dielectric capping layer to expose the conductive features, so as to form a plurality of spacer features respectively filled in the recesses. Each of the dielectric capping layer and the dielectric cover layer is made of a dielectric material doped with metal oxide.

In accordance with some embodiments of the present disclosure, the dielectric material for forming the dielectric capping layer is selected from SiO, SiCO, SiNO, SiCN, SiCON, or combinations thereof.

In accordance with some embodiments of the present disclosure, the metal oxide doped in the dielectric material for forming the dielectric capping layer is selected from AlOₓ, ZrOₓ, SnOₓ, PbOₓ, TiOₓ, WOₓ, CrOₓ, AsOₓ, or combinations thereof.

In accordance with some embodiments of the present disclosure, a doping concentration of the metal oxide in the dielectric material for forming the dielectric capping layer falls within a range of from 0.5% to 10%.

In accordance with some embodiments of the present disclosure, the dielectric material for forming the dielectric cover layer is SiCOH.

In accordance with some embodiments of the present disclosure, the metal oxide doped in the dielectric material for forming the dielectric cover layer is selected from AlOₓ, ZrOₓ, SnOₓ, PbOₓ, TiOₓ, WOₓ, CrOₓ, AsOₓ, or combinations thereof.

In accordance with some embodiments of the present disclosure, a doping concentration of the metal oxide in the dielectric material for forming the dielectric cover layer falls within a range of from 0.5% to 10%.

In accordance with some embodiments of the present disclosure, a method for manufacturing a semiconductor device includes: forming a dielectric layer; patterning the dielectric layer to form a plurality of spacer features, adjacent two of which are spaced apart from each other by a corresponding one of a plurality of recesses; and forming a plurality of conductive features respectively filled in the recesses. The dielectric layer is made of a dielectric material doped with metal oxide.

In accordance with some embodiments of the present disclosure, the dielectric material for forming the dielectric layer is SiCOH.

In accordance with some embodiments of the present disclosure, the metal oxide doped in the dielectric material for forming the dielectric layer is selected from AlOₓ, ZrOₓ, SnOₓ, PbOₓ, TiOₓ, WOₓ, CrOₓ, AsOₓ, or combinations thereof. In accordance with some embodiments of the present disclosure, a doping concentration of the metal oxide in the dielectric material for forming the dielectric layer falls within a range of from 0.5% to 10%.

In accordance with some embodiments of the present disclosure, a semiconductor device includes a conductive structure, a spacer feature and an interconnect layer. The conductive structure includes a first conductive feature and a second conductive feature. The spacer feature is configured to space the first and second conductive features apart from each other, and includes a spacer element that is disposed between the first and second conductive features. The interconnect layer includes a conductive interconnect that is electrically connected to one of the first and second conductive features. The spacer element is made of a dielectric material doped with metal oxide.

In accordance with some embodiments of the present disclosure, The dielectric material for forming the spacer element is SiCOH.

In accordance with some embodiments of the present disclosure, the metal oxide doped in the dielectric material for forming the spacer element is selected from AlOₓ, ZrOₓ, SnOₓ, PbOₓ, TiOₓ, WOₓ, CrOₓ, AsOₓ, or combinations thereof.

In accordance with some embodiments of the present disclosure, a doping concentration of the metal oxide in the dielectric material for forming the spacer element falls within a range of from 0.5% to 10%.

In accordance with some embodiments of the present disclosure, the spacer feature further includes a spacer film that covers side and bottom surfaces of the spacer element, and that is made of a dielectric material doped with metal oxide.

In accordance with some embodiments of the present disclosure, the dielectric material for forming the spacer film is selected from SiO, SiCO, SiNO, SiCN, SiCON, or combinations thereof.

In accordance with some embodiments of the present disclosure, the metal oxide doped in the dielectric material for forming the spacer film is selected from AlOₓ, ZrOₓ, SnOₓ, PbOₓ, TiOₓ, WOₓ, CrOₓ, AsOₓ, or combinations thereof.

In accordance with some embodiments of the present disclosure, a doping concentration of the metal oxide in the dielectric material for forming the spacer film falls within a range of from 0.5% to 10%.

In accordance with some embodiments of the present disclosure, each of the first and second conductive features includes a conductive element, and a barrier film that covers side and bottom surfaces of the conductive element.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
preparing a conductive structure that includes a plurality of conductive features, adjacent two of which are spaced apart from each other by a corresponding one of a plurality of recesses;
conformally forming a dielectric capping layer on the conductive structure;
forming a dielectric cover layer on the dielectric capping layer to fill the recesses; and
removing a portion of the dielectric cover layer and a portion of the dielectric capping layer to expose the conductive features, so as to form a plurality of spacer features respectively filled in the recesses;
wherein each of the dielectric capping layer and the dielectric cover layer is made of a dielectric material doped with metal oxide.

2. The method according to claim 1, wherein the dielectric material for forming the dielectric capping layer is selected from SiO, SiCO, SiNO, SiCN, SiCON, or combinations thereof.

3. The method according to claim 1, wherein the metal oxide doped in the dielectric material for forming the dielectric capping layer is selected from AlOₓ, ZrOₓ, SnOₓ, PbOₓ, TiOₓ, WOₓ, CrOₓ, AsOₓ, or combinations thereof.

4. The method according to claim 1, wherein a doping concentration of the metal oxide in the dielectric material for forming the dielectric capping layer falls within a range of from 0.5% to 10%.

5. The method according to claim 1, wherein the dielectric material for forming the dielectric cover layer is SiCOH.

6. The method according to claim 1, wherein the metal oxide doped in the dielectric material for forming the dielectric cover layer is selected from AlOₓ, ZrOₓ, SnOₓ, PbOₓ, TiOₓ, WOₓ, CrOₓ, AsOₓ, or combinations thereof.

7. The method according to claim 1, wherein a doping concentration of the metal oxide in the dielectric material for forming the dielectric cover layer falls within a range of from 0.5% to 10%.

8. A method for manufacturing a semiconductor device, comprising:
forming a dielectric layer;
patterning the dielectric layer to form a plurality of spacer features, adjacent two of which are spaced apart from each other by a corresponding one of a plurality of recesses; and
forming a plurality of conductive features respectively filled in the recesses;
wherein the dielectric layer is made of a dielectric material doped with metal oxide.

9. The method according to claim 8, wherein the dielectric material for forming the dielectric layer is SiCOH.

10. The method according to claim 8, wherein the metal oxide doped in the dielectric material for forming the dielectric layer is selected from AlOₓ, ZrOₓ, SnOₓ, PbOₓ, TiOₓ, WOₓ, CrOₓ, AsOₓ, or combinations thereof.

11. The method according to claim 8, wherein a doping concentration of the metal oxide in the dielectric material for forming the dielectric layer falls within a range of from 0.5% to 10%.

12. A semiconductor device comprising:
a conductive structure including a first conductive feature and a second conductive feature;
a spacer feature configured to space the first and second conductive features apart from each other, and including a spacer element that is disposed between the first and second conductive features; and
an interconnect layer including a conductive interconnect that is electrically connected to one of the first and second conductive features;
wherein the spacer element is made of a dielectric material doped with metal oxide.

13. The semiconductor device according to claim 12, wherein the dielectric material for forming the spacer element is SiCOH.

14. The semiconductor device according to claim 12, wherein the metal oxide doped in the dielectric material for forming the spacer element is selected from AlOₓ, ZrOₓ, SnOₓ, PbOₓ, TiOₓ, WOₓ, CrOₓ, AsOₓ, or combinations thereof.

15. The semiconductor device according to claim 12, wherein a doping concentration of the metal oxide in the dielectric material for forming the spacer element falls within a range of from 0.5% to 10%.

16. The semiconductor device according to claim 12, wherein the spacer feature further includes a spacer film that covers side and bottom surfaces of the spacer element, and that is made of a dielectric material doped with metal oxide.

17. The semiconductor device according to claim 16, wherein the dielectric material for forming the spacer film is selected from SiO, SiCO, SiNO, SiCN, SiCON, or combinations thereof.

18. The semiconductor device according to claim 16, wherein the metal oxide doped in the dielectric material for forming the spacer film is selected from AlOₓ, ZrOₓ, SnOₓ, PbOₓ, TiOₓ, WOₓ, CrOₓ, AsOₓ, or combinations thereof.

19. The semiconductor device according to claim 16, wherein a doping concentration of the metal oxide in the dielectric material for forming the spacer film falls within a range of from 0.5% to 10%.

20. The semiconductor device according to claim 12, wherein each of the first and second conductive features includes a conductive element, and a barrier film that covers side and bottom surfaces of the conductive element.
